(19) United States
(12) Patent Application Publication
(10) Pub. No.: US 2026/0060069 A1
(43) Pub. Date: Feb. 26, 2026

(54) VERTICAL POWER DELIVERY MODULE INCLUDING A TRANS-INDUCTOR VOLTAGE REGULATOR

(71) Applicant: TEXAS INSTRUMENTS INCORPORATED, Dallas, TX (US)

(72) Inventors: Elie Libbos, Dallas, TX (US); Sombuddha Chakraborty, Redwood City, CA (US)

(21) Appl. No.: 19/042,560

(22) Filed: Jan. 31, 2025

Related U.S. Application Data
(60) Provisional application No. 63/686,357, filed on Aug. 23, 2024.

(51) Int. Cl. H01L 23/522; H01L 23/29; H01L 23/528

(52) U.S. Cl. CPC H01L 23/5227; H01L 23/29; H01L 23/5223; H01L 23/5286

(57) ABSTRACT

A power module includes a substrate having first and second surfaces and first, second, and third metal interconnects. A semiconductor die on the first surface is coupled to the first metal interconnect. An encapsulation material has third and fourth opposing surfaces. The third surface is on the second surface. Primary inductors in the encapsulation material have a first lateral segment, a first vertical segment extending between a first end of the first lateral segment and the third surface, and a second vertical segment extending from a second end of the first lateral segment to the fourth surface. Secondary inductors have a second lateral segment and third and fourth vertical segments extending from ends of the second lateral segment to the third surface. A pair of adjacent third vertical segments are coupled via the second metal interconnect. A pair of adjacent fourth vertical segments are coupled via the third metal interconnect.

### CROSS-REFERENCE TO RELATED APPLICATIONS

This application claims priority to U.S. Provisional Application No. 63/686,357, filed Aug. 23, 2024, titled “Vertical Transinductor Voltage Regulators (TLVR),” which is hereby incorporated by reference.

### BACKGROUND

A multiphase power converter includes multiple output power phases coupled in parallel. Each power phase may include a pair of transistors (e.g., a half bridge) coupled to an inductor. A controller controls the timing of the transistors within the power phases. A trans-inductor voltage regulator (TLVR) is a multiphase power converter that includes a serially-connected set of “secondary” inductors. Each secondary inductor is magnetically coupled to a corresponding “primary” inductor of a power phase of the regulator. Through magnetic coupling between the primary and secondary inductors, the current through the primary inductors of the power phases adjusts (increase or decrease) more rapidly, thereby providing a faster transient response than would have been the case absent the secondary inductors.

### SUMMARY

In one example, a power module includes a substrate having first and second opposing surfaces and first, second, and third metal interconnects. A semiconductor die on the first surface is coupled to the first metal interconnect. An encapsulation material has third and fourth opposing surfaces. The third surface is on the second surface. Primary inductors in the encapsulation material have a first lateral segment, a first vertical segment extending between a first end of the first lateral segment and the third surface, and a second vertical segment extending from a second end of the first lateral segment to the fourth surface. Secondary inductors in the encapsulation material have a second lateral segment, and third and fourth vertical segments extending from respective ends of the second lateral segment to the third surface, in which a pair of adjacent third vertical segments are coupled via the second metal interconnect, and a pair of adjacent fourth vertical segments are coupled via the third metal interconnect.

In another example, a system includes a circuit board having first and second opposing surfaces and a first integrated circuit on the first surface. A trans-inductor voltage regulator (TLVR) module is on the second surface and is coupled to the first integrated circuit through the circuit board. The TLVR module includes a substrate having third and fourth opposing surfaces and first, second, and third metal interconnects. A semiconductor die is on the third surface and is coupled to the first metal interconnect. An encapsulation material has a fifth and sixth opposing surfaces. The sixth surface is on the fourth surface. Primary inductors are in the encapsulation material. Each primary inductor has a first lateral segment, a first vertical segment extending between a first end of the first lateral segment and the first surface, and a second vertical segment extending from a second end of the first lateral segment to the sixth surface. Secondary inductors are in the encapsulation material. Each secondary inductor has a second lateral segment, and third and fourth vertical segments extending from respective ends of the second lateral segment to the fifth surface. Each pair of adjacent third vertical segments are coupled via the second metal interconnect, and a pair of adjacent fourth vertical segments are coupled via the third metal interconnect.

### BRIEF DESCRIPTION OF THE DRAWINGS

FIG. 1 is a diagram of a system including a vertical power delivery (VPD) module, which includes a trans-inductor voltage regulator (TLVR), in an example.

FIG. 2 is a schematic diagram of at least a portion of the VPD of FIG. 1, in an example.

FIG. 3 is a schematic diagram of the VPD of FIG. 1, in an example.

FIG. 4 is a schematic diagram of primary and secondary inductors of the TLVR of FIG. 1, in an example.

FIG. 5 is a top-down view of a surface of a substrate of the VPD, in an example.

FIG. 6 is a side view of the magnetic cores of a four-phase TLVR, in an example.

FIG. 7 is a schematic diagram of primary inductors and secondary inductors a four-phase TLVR, in an example.

FIG. 8 is a schematic diagram illustrating directions of currents in two pairs of primary/secondary inductors of a TLVR, in an example.

FIG. 9 is a perspective view of the primary inductors and secondary inductors of a four-phase TLVR, in an example.

FIG. 10 is a bottom view of the primary and secondary inductor pairs of the four-phase TLVR of FIG. 9, in an example.

### DETAILED DESCRIPTION

The same reference numbers or other reference designators are used in the drawings to designate the same or similar (either by function and/or structure) features.

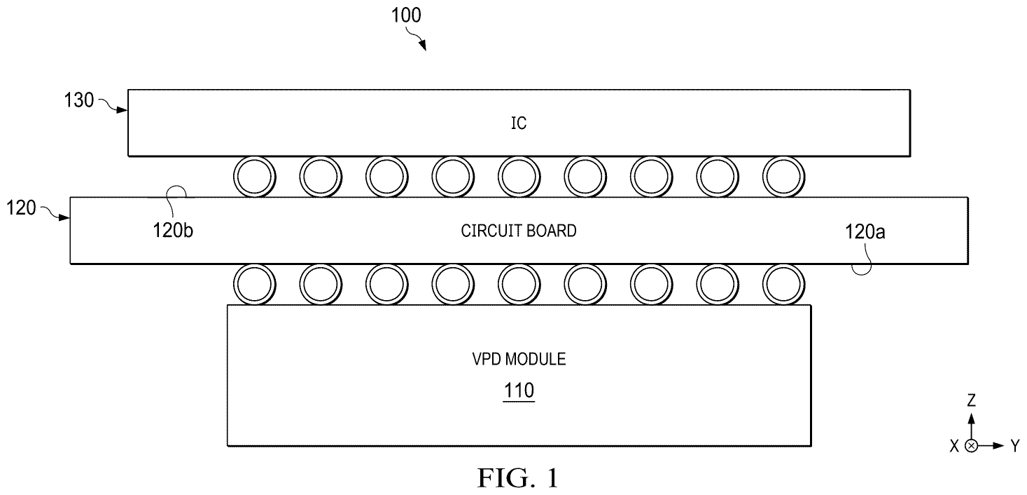

FIG. 1 is a schematic diagram of a system 100 which includes an integrated circuit (IC) 130 (e.g., a processor, a general purpose central processing unit (CPU), a graphical processing unit (GPU), etc.) coupled to one surface 120b of a circuit board 120 (e.g., a printed circuit board) and a vertical power delivery (VPD) module 110 coupled to the opposing surface 120a of the circuit board 120. In one example, VPD module 110 and IC 130 attach to circuit board 120 by way of ball grid arrays. VPD module 110 includes a voltage regulator such as a trans-inductor voltage regulator (TLVR). VPD module 110 provides power through electrical connections in circuit board 120 (e.g., traces and vias) to IC 130. By stacking the VPD module 110 vertically (e.g., along a z-axis of FIG. 1) with respect to the IC 130, the electrical connection of circuit board 120 between VPD module 110 and IC 130 can be shorter than a case where power module was placed laterally (e.g., along the x/y axes) next to the IC 130 on the same surface of circuit board 120. With shorter electrical connections to transmit power from VPD module 110 to IC 130, less power is lost (and wasted) to the parasitic resistance of the electrical connections. Further, by arranging VPD module 110 on a surface of circuit board 120 opposite that of IC 130, the overall footprint of system 100 can be reduced, and more space can be available on the circuit board for other components.

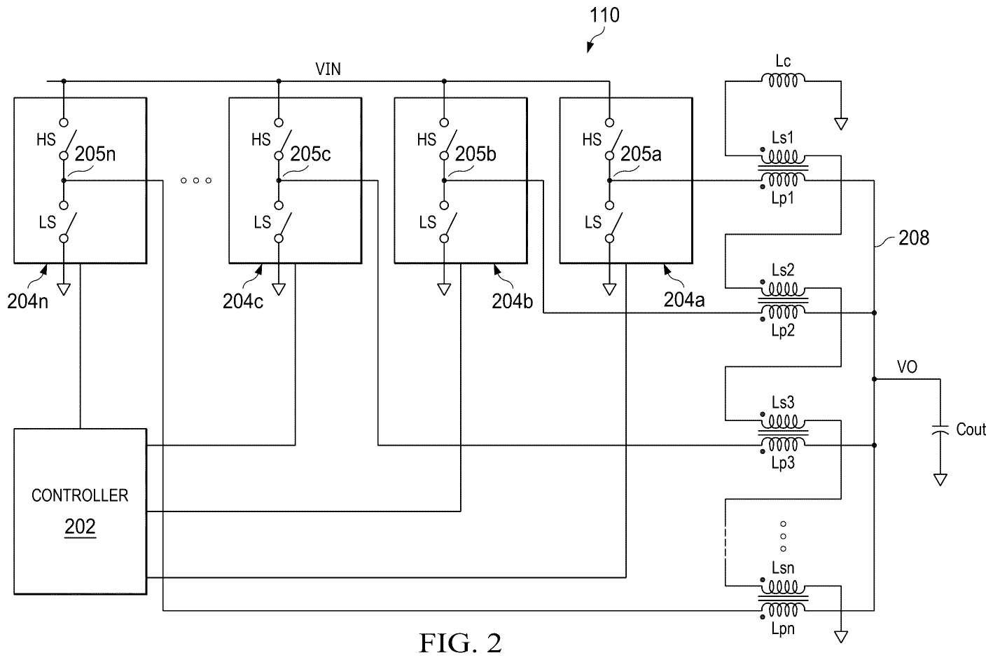

FIG. 2 is a schematic diagram of at least a portion of VPD module 110. VPD module 110 includes an n-phase TLVR which includes a controller 202, half-bridges 204a, 204b, 204c, . . . , 204n (collectively half-bridges 204), primary inductors Lp1, Lp2, Lp3, . . . , Lpn (collectively, primary inductors Lp), secondary inductors Ls1, Ls2, Ls3, . . . , Lsn (collectively, secondary inductors Ls), and a compensation inductance Lc. Compensation inductance Lc adjusts the transient performance of the TLVR. Compensation inductance Lc may be provided by a physical inductor or the parasitic inductance of the traces connecting the secondary inductors Ls and the leakage inductance of the secondary inductors. In one example, VPD module 110 includes a four-phase TLVR, n is 4. As a four-phase TLVR, VPD module 110 includes four half-bridges 204, four primary inductors Lp, and four secondary inductors Ls.

Half-bridge 204a includes a high side (HS) switch (e.g., a transistor) coupled to a low side (LS) switch (e.g., a transistor) at a switching terminal 205a. Half-bridges 204b, 204c, and 204n are similarly constructed and have corresponding switching terminals 205b, 205c, and 205n. Switching terminal 205a-205n are collectively referred to as switching terminals 205. An input voltage VIN is provided to one terminal of the HS switches. One terminal of each primary inductor Lp is coupled to a corresponding switching terminal 205. The other terminals of the primary inductors Lp are coupled together at an output terminal 208, which provides output voltage VO. An output capacitor Cout is coupled between the output terminal 208 and ground.

Controller 202 includes an output coupled to each half-bridge 204. Controller 202 can control which of the HS or LS switches is closed at any point in time. Controller 202 controls the duty cycle of each half-bridge 204 while operating the half-bridges with a phase delay. For example, for a two phase TLVR, each half-bridge is operated 180 degrees out of phase with respect to the other half-bridge. In a four phase TLVR, such as that shown in FIG. 2, controller 202 operates the half-bridges 90 degrees out of phase with respect to each other.

Secondary inductors Ls and compensation inductor Lc are coupled in series between ground terminals. Each secondary inductor Ls is magnetically coupled to a corresponding primary inductor Lp. For example, secondary inductors Ls1, Ls2, Ls3, and Lsn are magnetically coupled to corresponding primary inductors Lp1, Lp2, Lp3, and Lpn. In one example, each secondary inductor Ls is within the same encapsulation material as its corresponding primary inductor. In one example, the encapsulation material is a magnetic material, referred to herein as a magnetic core. By encapsulating corresponding primary and secondary inductors in the same magnetic core, each such pair of primary and secondary inductors forms a transformer. Each pair of primary and secondary inductors encapsulated in the same magnetic material is referred to herein as a primary/secondary pair.

A change in current in one of the primary or secondary inductors of a given primary/secondary pair induces a current in the other inductor of that pair. Upon occurrence of a sudden change in load condition (e.g., current from the VPD to IC 130 suddenly increases or decreases), a change in current through one of the primary inductors Lp induces a corresponding current in its corresponding magnetically-coupled secondary inductor Ls. Because the secondary inductors Ls are coupled in series, the same induced current flows through the other secondary inductors Ls thereby inducing a voltage back into their counterpart primary inductors. In this way, a TLVR is capable of having a faster transient response than a multiphase converter without a loop of secondary inductors, all else being equal.

The lefthand side of primary inductors Lp is the “dotted end” and the righthand side is the non-dotted end. The dotted ends of primary inductors Lp are coupled to the switching terminals 205, and the non-dotted ends are coupled together at the righthand side of the primary inductors. The lefthand sides of secondary inductors Ls are also the dotted ends. Because the secondary inductors Ls are coupled in series, the non-dotted end of each secondary inductor is coupled to the dotted end of the next secondary inductor in the serial loop of secondary inductors. The examples described herein pertain to an arrangement of primary inductors Lp and secondary inductors Ls such that the non-dotted end-to-dotted end connections (traces, conductors, etc.) between adjacent secondary inductors Ls are not located through the magnetic material which magnetically couples each pair of primary and secondary inductors. Otherwise, if such connections passed through the magnetic material, the inductance and coupling between primary and secondary winding would be altered (e.g., reduced). The resistance of the secondary winding would also be altered (e.g., increased).

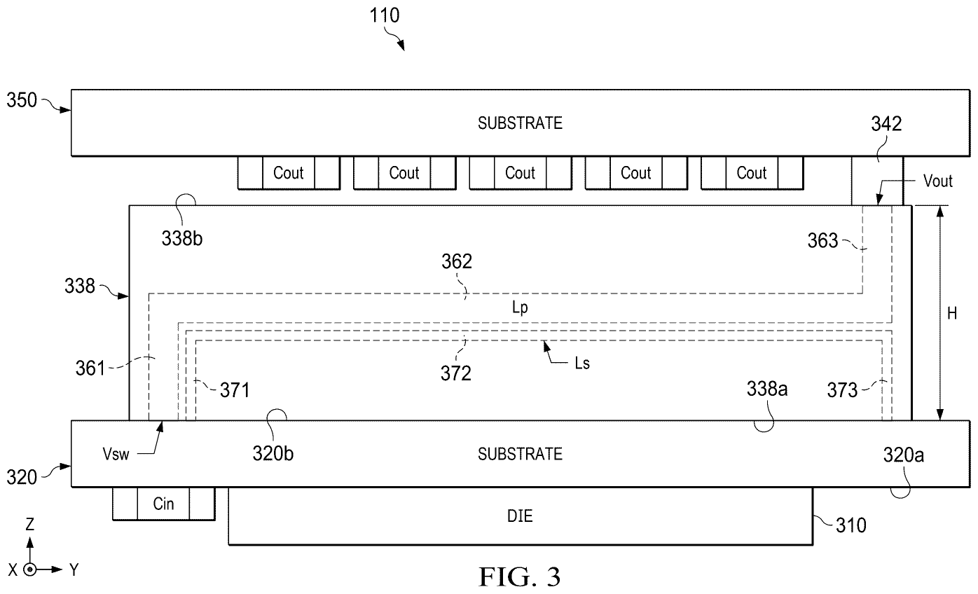

FIG. 3 is a schematic diagram of VPD module 110 which includes a semiconductor die 310, substrates 320 and 350, and magnetic material 338 containing primary inductors Lp and secondary inductors Ls. Magnetic material 338 may include ferrite, powdered iron, amorphous and nanocrystalline core, etc., embedded in an insulation material (e.g., epoxy, resin, etc.). One example of magnetic material 338 is a magnetic mold compound. The magnetic material can increase overall inductance of primary inductors Lp and secondary inductors Ls while providing/improving direct current (DC) electrical insulation between the inductors. Each pair of magnetically-coupled primary and secondary inductors Lp and Ls is stacked vertically within magnetic material 338 in the example of FIG. 3 with each primary inductor Lp vertically overlapping (e.g., along the z-axis of FIG. 3) its corresponding secondary inductor Ls. Substrate 320 has opposing surfaces 320a and 320b. Magnetic material 338 has opposing surfaces 338a and 338b. Semiconductor die 310 is on surface 320a of substrate 320 and surface 338a of magnetic material 338 is on surface 320b of substrate 320. Substrate 350 is on surface 338b of substrate 338 and is coupled to surface 338b via metal interconnects 342. In one example, semiconductor die 310 includes controller 202 and half-bridges 204. In some examples, semiconductor die 310, substrate 320, primary inductors Lp, secondary inductors Ls, and magnetic material 338 are part of a packaged integrated circuit.

Each primary inductor Lp includes a lateral segment 362 and vertical segments 361 and 363. Each lateral segment of primary inductor Lp may extend along a first axis (e.g., z-axis of FIG. 3), and each vertical segment may extend along a second axis angled from the first axis (e.g., x-axis or y axis of FIG. 3). Vertical segment 361 extends between one end of lateral segment 362 and surface 338a of magnetic material 338, where a portion of vertical segment 361 is exposed by magnetic material 338 and forms an output terminal (e.g., output terminal 208 of FIG. 2) that are electrically coupled to metal interconnects 342. Via metal interconnects 342, the output terminal can be coupled to other components, such as Cout Caps as shown in FIG. 3, as well as circuit board 120 and IC 130 of FIG. 1. Also, vertical segment 362 extends from the opposing end of lateral segment 362 and surface 338b of magnetic material 338, where a portion of vertical segment 362 is exposed by magnetic material 338 and coupled to a switching terminal (e.g., one of switching terminals 205a-n) via a pad on surface 320b of substrate 320 and interconnects (e.g., traces and vias) in substrate 320.

Also, each secondary inductor Ls includes a lateral segment 372 and vertical segments 371 and 373. Each lateral segment of secondary inductor Ls may extend along the same first axis (e.g., z-axis of FIG. 3) as a lateral segment of the corresponding primary inductor Lp, and each vertical segment of secondary inductor Ls may extend along the same second axis (e.g., x-axis or y-axis of FIG. 3) as a vertical segment of the corresponding primary inductor Lp. Vertical segment 371 of each secondary inductor Ls extends between one end of lateral segment 372 and surface 338a of magnetic material 338, and the other vertical segment 372 extends from the opposing end of lateral segment 372 and surface 338a. Portions of both vertical segments 372 can be exposed by magnetic material 338 and can be electrically insulated from the output terminal and switching terminal by magnetic material 338.

Through metal interconnects 342 and metal interconnects of substrate 350, vertical segments 363 of the primary inductors Lp are coupled together and to one or more capacitors Cout. Capacitors Cout also are coupled together via metal interconnects (e.g., pads on surface 320a of substrate 350. One or more input capacitors Cin also may be included and connected together by metal interconnects on substrate 320. Also, each vertical end 361 of primary inductors Lp is coupled through metal interconnects (e.g., pad on surface 320b of substrate 320, traces and vias in substrate 320, etc.) to a corresponding switching terminal 205 on semiconductor die 310, as described above.

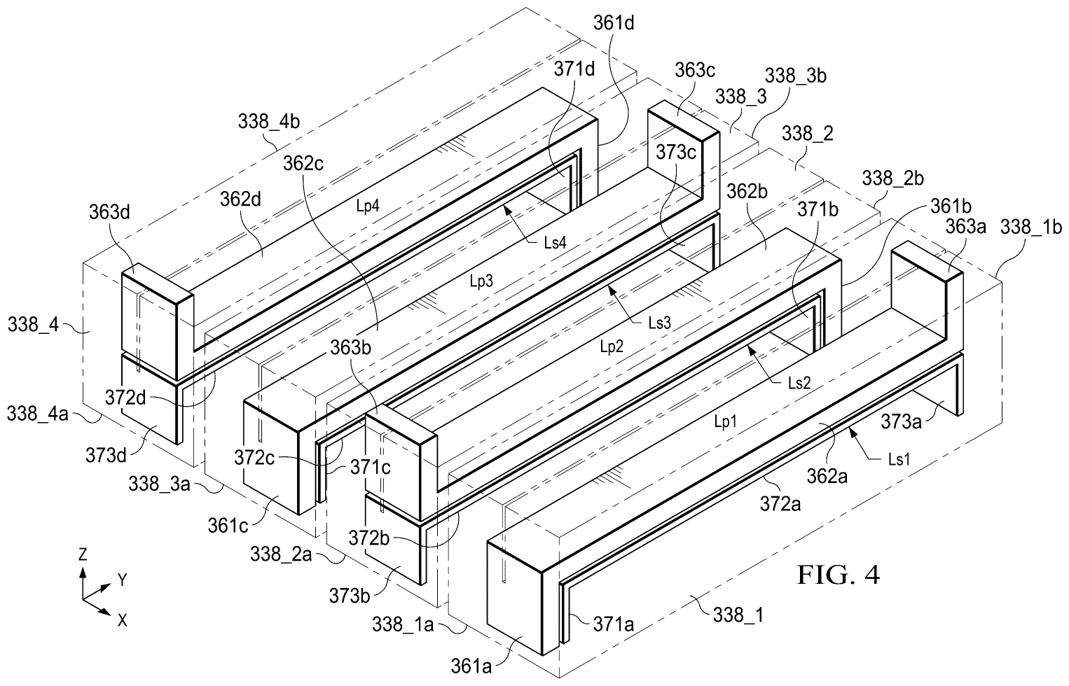

FIG. 4 is a perspective view of the primary inductors Lp and secondary inductors Ls in a four-phase TLVR. The primary inductors Lp include inductors Lp1, Lp2, Lp3, and Lp4. The secondary inductors include inductors Ls1, Ls2, Ls3, and Ls4. In the example shown in FIG. 4, primary inductors Lp1-Lp4 vertically overlap (e.g., along z-axis of FIG. 4) with respective secondary inductors Ls1-Ls4. Each pair of primary and secondary inductors is covered by magnetic material 338. Primary and secondary inductors Lp1 and Ls1 are in magnetic material 338_1. Primary and secondary inductors Lp2 and Ls2 are in magnetic material 338_2. Primary and secondary inductors Lp3 and Ls3 are in magnetic material 338_3. Primary and secondary inductors Lp4 and Ls4 are in magnetic material 338_4. In some examples, magnetic material 338 of adjacent pairs of primary and secondary inductors can be spaced apart to improve electrical insulation.

Primary inductor Lp1 has a lateral segment 362a and vertical segments 361a and 363a. Vertical segment 361a extends from one end of lateral segment 362a to bottom surface 338_1a of magnetic material 338_1, and vertical segment 363a extends from the other end of lateral segment 362a to top surface 338_1b of magnetic material 338_1. Primary inductor Lp2 has a lateral segment 362b and vertical segments 361b and 363b. Vertical segment 361b extends from one end of lateral segment 362b to bottom surface 338_2a of magnetic material 338_2, and vertical segment 363b extends from the other end of lateral segment 362b to top surface 338_2b of magnetic material 338_2. Primary inductor Lp3 has a lateral segment 362c and vertical segments 361c and 363c. Vertical segment 361c extends from one end of lateral segment 362c to bottom surface 338_3a of magnetic material 338_3, and vertical segment 363c extends from the other end of lateral segment 362c to top surface 338_3b of magnetic material 338_3. Primary inductor Lp4 has a lateral segment 362d and vertical segments 361d and 363d. Vertical segment 361d extends from one end of lateral segment 362d to bottom surface 338_4a of magnetic material 338_4, and vertical segment 363d extends from the other end of lateral segment 362d to top surface 338_4b of magnetic material 338_4.

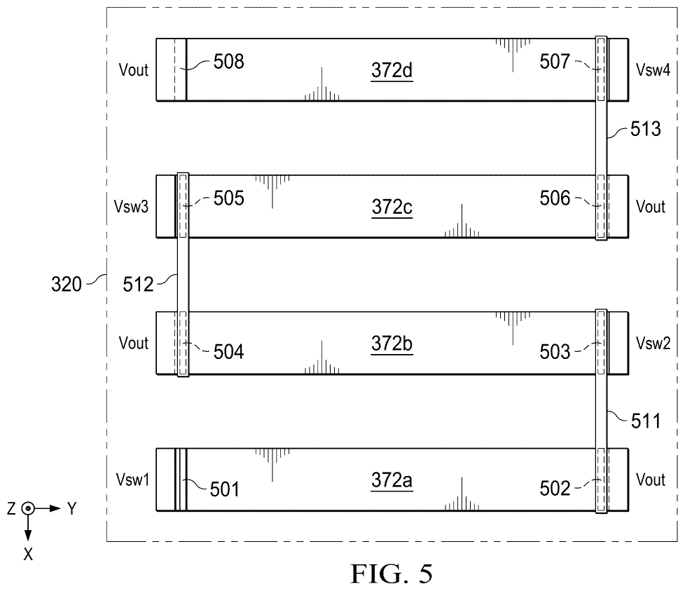

The four primary/secondary inductor pairs in FIG. 4 are parallel to each other along an axis (e.g., x-axis or y-axis of FIG. 4). The pair of primary inductor Lp2 and secondary inductor Ls2 is arranged in a reverse orientation with respect to primary inductor Lp1 and secondary inductor Ls1 such that the dotted ends of the Lp2 and Ls1 are on at the opposite sides of the respective magnetic materials 338_2 and 338_1. Similarly, the pair of primary inductor Lp3 and secondary inductor Ls3 is reversed with respect to the pair of primary inductor Lp2 and secondary inductor Ls2. Further, the pair of primary inductor Lp4 and secondary inductor Ls4 is reversed with respect to the pair of primary inductor Lp3 and secondary inductor Ls3. By reversing the locations of the connections to the switching terminals from adjacent pairs of primary and secondary inductors to the respective half-bridges, connections between the secondary inductors Ls in series can be made via metal interconnects on substrate 320 rather than having such connections pass through magnetic materials 338-1 through 338-4. The connections between adjacent secondary inductors Ls are illustrated in FIG. 5. Such arrangements can reduce the complexity of forming the secondary inductors Ls and the electrical connections between them. Moreover, having the electrical connections in the magnetic material can reduce the amount of magnetic material covering the inductors, which can reduce the overall inductance, increase loss in the secondary inductors, and degrade electrical isolation between the secondary inductors and the primary inductors. Examples of arrangements of primary and second inductors shown in FIG. 4 and subsequent figures allow the connections between the secondary inductors to be formed in the substrate and outside the magnetic material, and can address at least some of the issues described above.

FIG. 5 is a top-down view of surface 320b of substrate 320 illustrating where vertical segments 361a, 361b, 361c, and 361d of corresponding primary inductors Lp1-Lp4 land on substrate 320. Because vertical segments 361a-361d are coupled to switching terminals of the corresponding half-bridges (e.g., half-bridges 204 in FIG. 2), the landing pads on surface 320b of substrate 320 for vertical segments 361a-361d are identified as Vsw1 (for vertical segment 361a), Vsw2 (for vertical segment 361b), Vsw3 (for vertical segment 361c), and Vsw4 (for vertical segment 361d). The four blocks labeled Vout represent portions of the other vertical segments (363a-363d) of the primary inductors Lp1-Lp4 exposed in surfaces 338b of magnetic material 338 facing away from substrate 320 (e.g., 338_1b, 338_2b, 338_3b, and 338_4b).

FIG. 5 also identifies the landing pads 501-508 of the vertical segments of the secondary inductors Ls on surface 320b of substrate 320. Landing pads 501 and 502 correspond to vertical segments 371a and 373a, respectively, of secondary inductor Ls1. Landing pads 503 and 504 correspond to vertical segments 371b and 373b, respectively, of secondary inductor Ls2. Landing pads 505 and 506 correspond to vertical segments 371c and 373c, respectively, of secondary inductor Ls3. Landing pads 507 and 508 correspond to vertical segments 371d and 373d, respectively, of secondary inductor Ls4. The lateral segments 372a through 372d of secondary inductors Ls1 through Ls4 are shown in dashed outline indicating that the secondary inductors'lateral segments are covered by the corresponding lateral segments 362a-362d (not specifically shown in FIG. 5) of primary inductors Lp1 through Lp4. Landing pads 501-508 are electrically isolated from output terminal 208 and switching terminals 205.

Substrate 320 includes metal interconnects 511, 512, and 513. Metal interconnect 511 couples together landing pads 502 and 503 and, accordingly, vertical segments 373a and 371b of secondary inductors Ls1 and Ls2. Metal interconnect 512 couples together landing pads 504 and 505 and, accordingly, vertical segments 373b and 371c of secondary inductors Ls2 and Ls3. Metal interconnect 513 couples together landing pads 506 and 507 and, accordingly, vertical segments 373c and 371d of secondary inductors Ls3 and Ls4. Metal interconnects 511, 512, and 513 on substrate 320 thereby serially connect together secondary inductors Ls1-Ls4. In some examples, metal interconnects 511, 512, and 513 can be below surface 320b of substrate 320. In some examples, metal interconnects 511, 512, and 513 can be on surface 320b and extends from (or merge with) landing pads 502, 503 (for 511), 504, 505 (for 512), and 506, 507 (for 513).

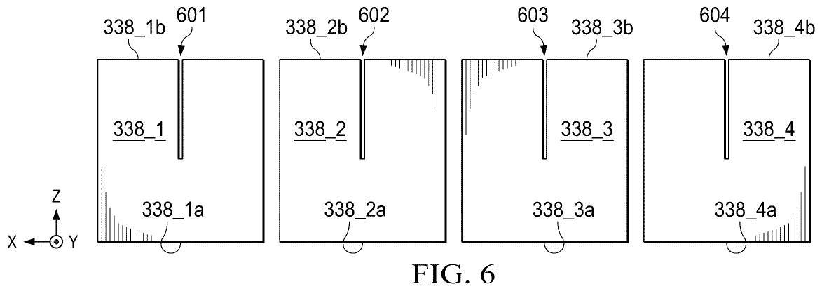

FIG. 6 is a side view of the four magnetic materials/cores 338_1 through 338_4. In FIG. 6, the primary and secondary inductors in the magnetic materials are not shown. In this example, each magnetic material 338a_1-338_4 includes a gap that extends vertically (e.g., along the z-axis of FIG. 6). Magnetic material 338_1 has a gap 601. Magnetic material 338_2 has a gap 602. Magnetic material 338_3 has a gap 603. Magnetic material 338_4 has a gap 604. Each gap 601-604 extends partially downward (e.g., along the z-axis of FIG. 6) from respective top surfaces 338_1b through 338_4b towards the opposing bottom surface 338_1a through 338_4a. Gaps 601-604 may also extend laterally along (or parallel with) the lateral segments of the primary and secondary inductors (e.g., along the x-axis or y-axis of FIG. 6), or otherwise extend along the flux path. The gap can be filed with air, or non-magnetic material (e.g., epoxy, resin, plastic, or ceramic spacer). Gaps 601-604 may be useful if magnetic material 338_1 through 338_4 has relatively a high magnetic permeability, where gaps 601-604 can limit the magnetic field to avoid saturating the magnetic cores.

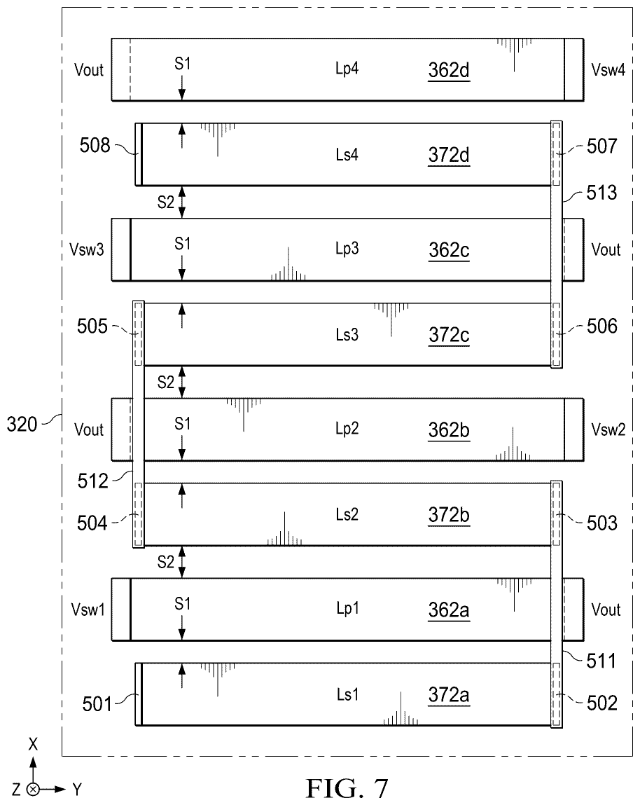

FIG. 7 is a schematic diagram of primary inductors Lp1-Lp4 and secondary inductors Ls1-Ls4 in which the lateral segments 362a-363d of the primary inductors and the lateral segments 372a-372d of the secondary inductors overlap laterally (e.g., along the x-axis or y-axis of FIG. 7) on substrate 320 along the x-axis instead of vertically as in FIGS. 3-6. S2 represents the distance between one pair of primary and secondary inductors and an adjacent primary/secondary inductor pair. For example, S2 represents the distance between lateral segment 362a of primary inductor Lp1 and lateral segment 372b of secondary inductor Ls2, the distance between lateral segment 362b of primary inductor Lp2 and lateral segment 372c of secondary inductor Ls3, and the distance between lateral segment 362c of primary inductor Lp3 and lateral segment 372d of secondary inductor Ls4. S1 represents the distance between the primary inductor and the secondary inductor of each primary/secondary inductor pair. For example, S1 represents the distance between lateral segment 362a of primary inductor Lp1 and lateral segment 372a of secondary inductor Ls1, the distance between lateral segment 362b of primary inductor Lp2 and lateral segment 372b of secondary inductor Ls2, the distance between lateral segment 362c of primary inductor Lp3 and lateral segment 372c of secondary inductor Ls3, and the distance between lateral segment 362d of primary inductor Lp4 and lateral segment 372d of secondary inductor Ls4. In one example, S1 is larger than S2. In another example, S1 is equal to S2. A benefit of the configuration of FIG. 7 is higher inductance and magnetic coupling depending on the coil and core dimensions and aspect ratios.

In the example of FIGS. 4-6, each pair of magnetically-coupled primary and secondary inductors are included within its own respective magnetic core. In another example, two pairs of primary/secondary inductors are included within one magnetic core. Accordingly, in the example of a four-phase TLVR, such a TLVR would include two magnetic cores—one magnetic core including two pairs of primary/secondary inductors and another magnetic core including the other two pairs of primary/secondary inductors.

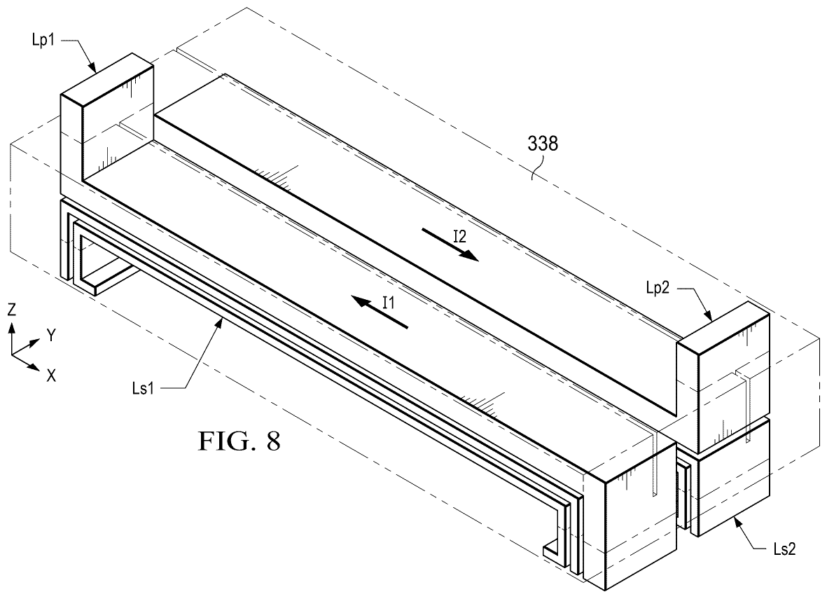

FIG. 8 is a schematic diagram of an example of one magnetic core/magnetic material 338 including two pairs of primary/secondary inductors. One pair includes primary inductor Lp1 and secondary inductor Ls1, and the other pair includes primary inductor Lp2 and secondary inductor Ls2. Magnetic material 338 can improve the magnetic coupling between primary inductor Lp1 and secondary inductor Ls1 and also the magnetic coupling between primary inductor Lp2 and secondary inductor Ls2. Magnetic material 338 also improve magnetic coupling between primary inductors Lp1 and Lp2. Because the switching terminals of primary inductors Lp1 and Lp2 are on opposite sides, current of different phases can flow in opposite directions in the lateral segments of primary inductors Lp1 and Lp2. For example, as shown in FIG. 8, current I1 flowing through primary inductor Lp1 flows in the opposite direction as current I2 through the adjacent primary inductor Lp2. Because currents I1 and I2 are in opposite directions, the magnetic flux generated by current I1 flowing through primary inductor Lp1 is canceled, to at least some extent, by the magnetic flux generated by current I2 flowing through primary inductor Lp2. Because of the reduced magnetic flux, the primary and secondary inductors in the example of FIG. 8 can have a larger inductance per unit volume, which allows shrinking of the primary and secondary inductors for the same current ripple. Such arrangements can reduce the overall footprints of the TLVR and of the VPD.

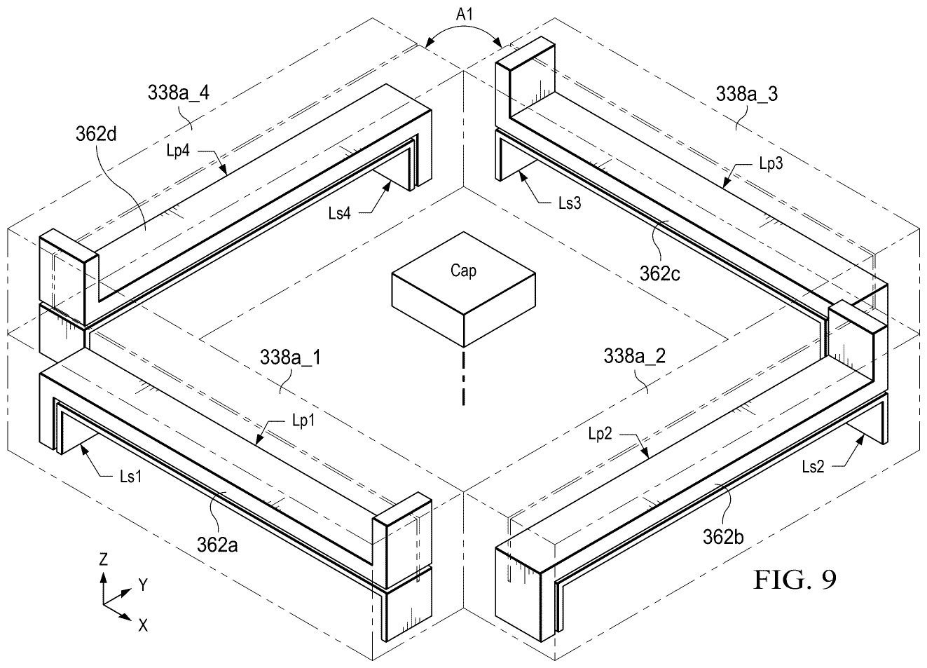

FIG. 9 is a perspective view of the primary inductors Lp and secondary inductors Ls in a four-phase TLVR in which the magnetically-coupled pairs of primary and secondary inductors are arranged on substrate 320 in a ring. In the example of FIG. 9, the ring is generally rectangularly shaped with each pair of primary and secondary inductors forming one side of the rectangle. Other examples of a ring of pairs of primary and secondary inductors may include a square, a parallelogram, a circle, etc., and including more than four pairs of primary and secondary inductors. The lateral segment 362a of primary inductor Lp1 is at an angle A1 with respect to the lateral segment 362b of adjacent primary inductor Lp2. Similar angles are formed between lateral segments 362b and 362c, between lateral segments 362c and 362d, and between lateral segments 362d and 362a. In one example, angle A1 is approximately 90 degrees. In other examples, the angle A1 between one pair of adjacent primary inductor lateral segments may different than the angle between another pair of lateral segments. Vertical segments 371 and 373 of some of the adjacent secondary inductors Ls, such as vertical segment 371b of Ls2 and vertical segment 373a of Ls1, are electrically coupled via metal interconnects of substrate 320 (not shown in FIG. 9). One or more capacitors, such as Cin and Cout, can be positioned within the interior of the ring of primary/secondary inductor pairs. Such arrangements can reduce the overall height (e.g., along the z-axis) of the system. In an example in which the magnetic material has a relatively high magnetic permeability, magnetic materials 338a_1 through 338a_4 in FIG. 9 may include a gap (e.g., gaps 601-604) as described above regarding FIG. 6. In an example in which the magnetic materials 338a_1 through 338a_4 include a magnetic material having a relatively low magnetic permeability, magnetic materials 338a_1 through 338a_4 do not include a gap.

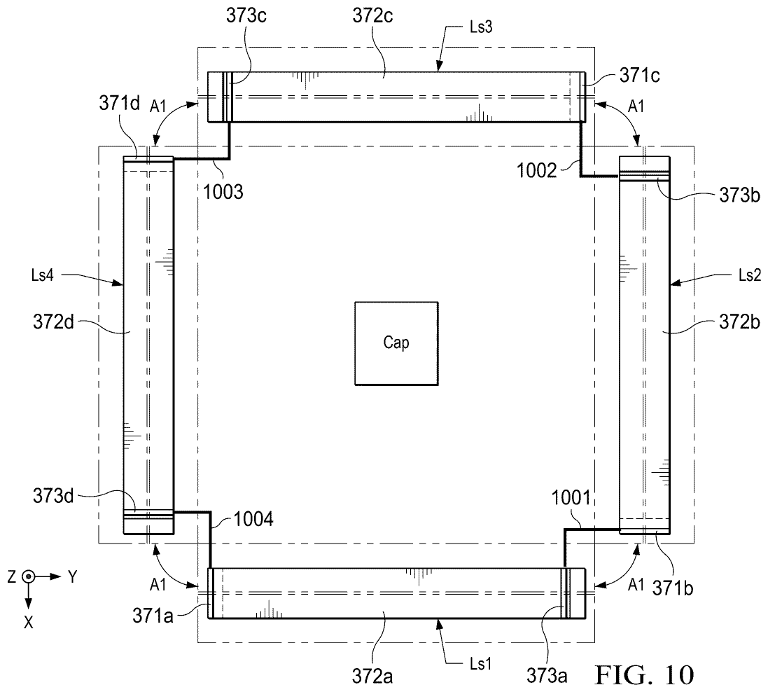

FIG. 10 is a bottom view of the ring of primary/secondary inductor pairs of FIG. 9. FIG. 10 also shows metal interconnects 1001, 1002, and 1003, which are provided on or in substrate 320 (not shown in FIG. 10). Metal interconnect 1001 couples vertical segment 373a of secondary inductor Ls1 to vertical segment 371b of secondary inductor Ls2. Metal interconnect 1002 couples vertical segment 373b of secondary inductor Ls2 to vertical segment 371c of secondary inductor Ls3. Metal interconnect 1003 couples vertical segment 373c of secondary inductor Ls3 to vertical segment 371d of secondary inductor Ls4. If the parasitic inductance of the combined metal interconnects 1001 through 1004 is sufficiently large to meet the transient performance requirement vertical segment 373d of secondary inductor Ls4 may be coupled via a metal interconnect 1004 to vertical segment 371a of secondary inductor Ls1 to form compensation inductance Lc. In another example, a separate inductor Lc can be coupled between respective vertical segments 373d and 371a.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on. ” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A power module, comprising:
a substrate having a first surface and a second surface opposing the first surface and first, second, and third metal interconnects;
a semiconductor die on the first surface and coupled to the first metal interconnect;
an encapsulation material having a third surface and a fourth surface opposing the third surface, the third surface on the second surface;
primary inductors in the encapsulation material, each primary inductor having a first lateral segment, a first vertical segment extending between a first end of the first lateral segment and the third surface, and a second vertical segment extending from a second end of the first lateral segment to the fourth surface; and
secondary inductors in the encapsulation material, each secondary inductor having a second lateral segment, and third and fourth vertical segments extending from respective ends of the second lateral segment to the third surface, in which a pair of adjacent third vertical segments are coupled via the second metal interconnect, and a pair of adjacent fourth vertical segments are coupled via the third metal interconnect.

2. The power module of claim 1, wherein the pair of adjacent third vertical segments are adjacent the first vertical segment of a first one of the primary inductors and the second vertical segment of a second one of the primary inductors; and
wherein the pair of adjacent fourth vertical segments are adjacent the second vertical segment of the first one of the primary inductors and the first vertical segment of the second one of the primary inductors.

3. The power module of claim 1, wherein the secondary inductors are serially-coupled via the adjacent fourth vertical segments and the third metal interconnects.

4. The power module of claim 1, wherein the first lateral segment of each of the primary inductors is parallel with the second lateral segment of a respective one of the secondary inductors.

5. The power module of claim 4, wherein the first lateral segment of each of the primary inductors overlaps vertically with the second lateral segment of a respective one of the secondary inductors.

6. The power module of claim 4, wherein the first lateral segment of each of the primary inductors overlaps laterally with the second lateral segment of a respective one of the secondary inductors.

7. The power module of claim 1, further comprising capacitors on at least one of the first or second surfaces of the substrate and coupled to the first metal interconnects.

8. The power module of claim 1, wherein the substrate is a first substrate, and the power module further comprises a second substrate on the fourth surface, and the second vertical segments are coupled to the second substrate.

9. The power module of claim 8, further comprising capacitors on the second substrate, wherein the second substrate includes fourth metal interconnects, and the capacitors are coupled to the second vertical segments via the fourth metal interconnects.

10. The power module of claim 1, wherein the first lateral segments of adjacent primary inductors are parallel to each other, and the encapsulation material includes a first core that encapsulates a pair of adjacent first lateral segments.

11. The power module of claim 10, further comprising a capacitor over and coupled to the primary inductors.

12. The power module of claim 1, wherein the first lateral segments of adjacent primary inductors are angled from each other.

13. The power module of claim 12, further comprising a capacitor surrounded by the primary inductors, the capacitor coupled to the primary inductors.

14. The power module of claim 1, wherein the encapsulation material includes a magnetic material.

15. The power module of claim 14, wherein the encapsulation material includes a gap that extends from the third or fourth surfaces and parallel to the first lateral segment of at least one of the primary inductors.

16. The power module of claim 1, wherein the semiconductor die includes half bridges each having a respective switching terminal, the first vertical segment of each of the primary inductors is coupled to a respective one of the switching terminals, and the second vertical segments of the secondary inductors are coupled to a power output.

17. The power module of claim 1, wherein the substrate, the semiconductor die, the encapsulation material, the primary inductors, and the secondary inductors are part of a packaged integrated circuit.

18. A system, comprising:
a circuit board having a first surface and a second surface opposing the first surface;
a first integrated circuit on the first surface; and
a trans-inductor voltage regulator (TLVR) module on the second surface and coupled to the first integrated circuit through the circuit board, the TLVR module including:
a substrate having a third surface and a fourth surface opposing the third surface and first, second, and third metal interconnects;
a semiconductor die on the third surface and coupled to the first metal interconnect;
an encapsulation material having a fifth surface and a sixth surface opposing the fifth surface, the sixth surface on the fourth surface;
primary inductors in the encapsulation material, each primary inductor having a first lateral segment, a first vertical segment extending between a first end of the first lateral segment and the first surface, and a second vertical segment extending from a second end of the first lateral segment to the sixth surface; and
secondary inductors in the encapsulation material, each secondary inductor having a second lateral segment, and third and fourth vertical segments extending from respective ends of the second lateral segment to the fifth surface, in which a pair of adjacent third vertical segments are coupled via the second metal interconnect, and a pair of adjacent fourth vertical segments are coupled via the third metal interconnect.

19. The system of claim 18, wherein the secondary inductors are serially-coupled via the adjacent fourth vertical segments and the third metal interconnects.

20. The system of claim 18, wherein the first lateral segment of each of the primary inductors overlaps the second lateral segment of a respective one of the secondary inductors between the fifth and sixth surfaces.

21. The system of claim 18, wherein the first lateral segments of adjacent primary inductors are parallel to each other, and the encapsulation material includes a first core that encapsulates a pair of adjacent first lateral segments.

22. The system of claim 18, wherein the first lateral segments of adjacent primary inductors are arranged in a ring within the encapsulation material.
